(19) United States
(12) Patent Application Publication
(10) Pub. No.: US 2011/0117454 A1
(43) Pub. Date: May 19, 2011

(54) ELECTRODE FOR ELECTROCHEMICAL CELLS

(75) Inventors: Bjorn Winther-Jensen, Mount Waverle Victoria (AU); Maria Forsyth, Ashburton (AU); Douglas Robert Macfarlane, East Brighton (AU)

(73) Assignee: Monash University, Clayton, Vic (AU)

(21) Appl. No.: 12/866,508

(22) PCT Filed: Feb. 6, 2009
(86) PCT No.: PCT/AU2009/000135

§ 371 Date: Jan. 13, 2011

(30) Foreign Application Priority Data
Feb. 8, 2008 (AU) 2008900593

(51) Int. Cl. H01M 4/60; H01M 4/52; H01M 4/58; H01M 2/02; H01B 1/12; H01B 1/02; H01B 1/04; C23C 16/44; C23C 16/50; B05D 5/12

(52) U.S. Cl. 429/402; 429/163; 429/213; 429/530; 429/535; 252/500; 252/512; 252/514; 252/513; 252/511; 427/58; 427/569; 427/115

(57) ABSTRACT

The invention relates to an electrode for oxygen reduction comprising a porous organic material and at least one inherently conducting polymer such as a charge transfer complex or a conductive polymer, optionally combined with a non-conducting polymer. A current conductor may be located intermediate the porous organic material and the inherently conductive polymer. The electrode is suitable for use with an ion-conducting membrane and fuel such as hydrogen, an alcohol or borohydride to form a fuel-cell. The electrode is also suitable for use with an anode, such as a reactive metal and an electrolyte to form a battery.

### FIELD OF THE INVENTION

This Invention relates to electrochemical cells such as batteries and fuel cells. Even more particularly the present invention relates to electrochemical cells having a metal or catalytically active anode and an electrode comprising an inherently conducting polymer.

### BACKGROUND OF THE INVENTION

In this specification where a document, act or item of knowledge is referred to or discussed, this reference or discussion is not an admission that the document, act or Item of knowledge or any combination thereof was at the priority date, publicly available, known to the public, part of common general knowledge; or known to be relevant to an attempt to solve any problem with which this specification is concerned.

While the present invention will be principally described with reference to use of a magnesium metal anode or an active catalytic platinum anode it will be readily appreciated that the present invention is not so limited, but can be extended electrochemical cells having a wide range of metal and catalytic anodes. In their broadest sense, electrochemical cells store or convert chemical energy and make it available in an electrical form. Electrochemical cells include energy sources such as batteries and fuel cells.

### Batteries

The term ‘battery’ typically refers to two or more electrochemical cells connected in series, however the term. Is also used to refer to a single cell. Batteries typically comprise an anode, a cathode and electrolyte in a seated container and are directly delivering electrical current.

There are myriad batteries commercially available. One of the best known types of commercial battery is the zinc-carbon battery which is packaged in a zinc container that also serves as an anode. Typically the cathode is a mixture of manganese dioxide and carbon powder. The electrolyte is a paste of zinc chloride and ammonium chloride dissolved in water.

One of the many patents directed to batteries includes U.S. Pat. No. 5,718,986, which teaches the use of batteries having a magnesium or aluminium anode, an inert cathode and a chlorite or hypochlorite based electrolyte for large scale applications such as providing power to cars.

A novel type of ‘paper’ battery has recently been developed at Rensellaer Polytechnic Institute (Flexible Energy Storage Devices Based on Nanocomposite Paper, 13 August 2007, Proc. Nat. Acad. Sci). The nanoengineered battery is lightweight, ultra thin and completely flexible and comprised of paper infused with aligned carbon nanotubes. An ionic liquid is used as the electrolyte. The nanotubes act as electrodes and allow the device to conduct electricity—functioning as both a lithium-ion battery and a supercapacitor. The paper batteries can be stacked to boost the total power output Paper is extremely biocompatible and these new batteries are potentially useful as power supplies for devices implanted in the body. The paper batteries have also boon shown to work without added electrolyte—the naturally occurring electrolytes in human sweat, blood and urine being suitable to activate the paper battery.

There is growing interest in compact, light weight, thin film (less than 1 mm thick) batteries for biomedical and blonic applications. Biocompatible batteries are in demand to power out a range of biological devices including devices for controlling release of hormones, providing electrical stimulation of cell-growth, operating artificial retinas, or releasing electrical stimulus through a heart pacemaker.

Many of these applications do not require high discharge currents but rather flexibility in shape and size. The strategy in developing such a device involves selecting materials which themselves, and any reaction products, are bio compatible. The accepted definition of biocompatibility is ‘the ability of a material to perform with an appropriate host response in a specific application’ (Williams D. F., ed, Definitions in Biomaterials. Progress in Biomedical Engineering, 4, Amsterdam, Elsevier Publishers 1987). Biocompatibility is a convolution of certain characteristics of materials. For example the material must exhibit characteristics such as low toxicity, and the physical and mechanical design must be suitable for the specific application and have long life, preferably matching the lifespan of the recipient, so they do not need to be surgically replaced.

### Fuel Cells

A fool cell, like a battery, converts chemical energy to electrical energy. However a battery typically holds a limited fuel supply in a sealed container whereas a fuel cell uses an ongoing supply of fuel to create a continuous flow of electricity. The external supply of fuel (the anode) and oxidant (the cathode) react in the presence of the electrolyte. Typically, reactants flow in and react to form reaction products which then flow out of the cell. The electrolyte remains in the cell.

One of the best known fuel cells is the polymer electrolyte membrane fuel cell (PEMFC) which comprises a proton-conducting polymer membrane (the electrolyte) which has an anode side and cathode side. At the anode side, hydrogen diffuses to an anode catalyst which causes the hydrogen to dissociate into protons and electrons. The protons flow through the proton-conducting polymer membrane to the cathode. Meanwhile, because the membrane is electrically Insulating, the electrons travel in another circuit, thus supplying power. On the cathode catalyst, oxygen molecules react with the electrons (that have passed through the circuit) and protons, to form water. The water then flows out of the cell.

The working of fuel cells is principally based on catalysis, separating the electrons and protons of the reactant fuel, and forcing the electrons to travel through a circuit, thus creating electrical power. The catalyst is typically comprised of particulate platinum group metal or alloy. One of the problems associated with fuel cells is that platinum is expensive and the construction of fuel cells is typically complex. Furthermore, these cells suffer from problems including drifting of the particles of platinum catalyst leading to significant, rapid diminution of the catalytic effect.(Yu et al, J. Power Sources 172 (2007) 145-154: Shao et al, J. Power Sources 171 (2007) 558-588)

Accordingly, there is an ongoing need for electrochemical cells that have optimised power output and simpler, more economic design. There is also an ongoing need for electrochemical cells that meet the design and energy requirements of tomorrow's devices, implantable medical equipment and transportation vehicles.

### SUMMARY OF THE INVENTION

The present invention provides an air-electrode comprising a porous organic malarial and at least one inherently conducting polymer.

The present invention provides an electrochemical cell comprising an encapsulating means that encloses:
(a) an electrode comprising a porous organic material and at least one Inherently conducting polymer,
(b) an anode, and
(c) an electrolyte intermediate the electrodes.

The surprising and novel aspect of the present invention is the use of an inherently conducting polymer (ICP), as part of an electrode. A further surprising and novel aspect of the present invention is the use of the aforesaid electrode in combination with an anode in an electrochemical cell, such as a metal-air battery or fuel-cell.

The electrolyte Intermediate the electrodes may be in any state. Typically, when the electrochemical cell is a battery, the electrolyte is a sold, liquid, gel or solution. Alternatively, when the electrochemical cell is a fuel cell, the electrolyte comprises a gas or vapour.

Accordingly, the present invention provides an electrochemical cell in the form of a fuel cell, the fuel cell comprising an encapsulating means that encloses:
(a) an electrode comprising a porous organic material and at least one inherently conducting polymer,
(b) an anode, and
(c) an electrolyte comprising a gas, intermediate the electrodes.

The present invention further provides an electrode comprising a porous material and an Inherently conducting polymer which can successfully be used in metal/air batteries and in fuel-cells or, for example, a hydrogen fuel-cell or a direct methanol fuel-cell. For the metal/air batteries, where normally highly salty and alkaline electrolytes are used, the preformance of the cell is limited by the area of the metal, not the electrode.

### Bio-Compatibility

For some applications the electrochemical cell of the present invention is bio-compatible and suitable for use in vivo. In this embodiment, typically the encapsulating means is bio-compatible. In a particularly preferred embodiment the encapsulating means and all the other components of the electrochemical cell are bio-compatible so that although surgery may be required to locate the bio-compatible electrochemical cell at its operating position within a host, no surgical intervention will be required to remove the electrochemical cell.

In a further preferred embodiment all the components of the electrochemical cell are both bio-compatible and biodegradable such that the components will decompose, dissolve or otherwise degrade over a period of time.

In a further embodiment the present invention provides a method of Imparting electrical stimulus using the bio-compatible electrochemical cell of the present invention. In this embodiment the electrical stimulus may be provided directly to living tissue, or indirectly through an implanted device such as a pacemaker or cochlear implant.

### Electrolyte

The electrolyte may be in any suitable state—solid, liquid or gas or combinations thereof. Typically, when the electrochemical cell is a battery, the electrolyte is a liquid, get or solution. Alternatively, when the electrochemical cell is a fuel cell, the electrolyte comprises a gas or vapour or is in the form of an ion-conducting membrane such as Nafion®.

For example, preferably the electrochemical cell is a battery having an electrolyte comprising one or more metal salts, including alkali metal or alkaline earth metal salts, such as halides or nitrates. The electrolyte is typically aqueous, and/or may comprise a gel. The gel could be formed, for example, from polyethylene oxide. The electrolyte may alternatively be non-aqueous such as, for example, an Ionic liquid or ionic liquid get.

### Electrolyte Additives

Various additives may be added to optimise the electrolyte characteristics. For example, additives may be chosen from the group comprising solvents that act as ‘swelling agents’, non-solvents, ionic-liquids and phosphates. The role of these additives is to enhance the interaction between the electrolyte and the conducting polymer, that is, to help optimise the three phase interface. For example, the additives may improve the structure of the conducting polymer by causing it to swell.

### Anode

Typically, the anode will contain metal, but the person skilled in the art will appreciate that other types of anodes can also be used in the electrochemical cell of the present invention. For example, the electrochemical cell may have a catalytically active anode or a non-metal anode.

When the electrochemical cell of the present invention is intended for in vivo use, typically the anode comprises a bio-compatible metal or metal alloy, such as magnesium or magnesium alloy. If the electrochemical cell is not Intended for use in vivo the metal alloy can be chosen from any metal that has a suitable electrochemical potential when compared to the ICP chosen for the cathode. The anode could include, for example, magnesium, aluminium, zinc, iron or lithium metals or their alloys.

In another embodiment of the present invention, the anode may comprise a metal catalyst in combination with other materials, or alternatively, the anode may not have any metal content whatsoever. For example, if the electrochemical cell is a common fuel cell, the anode could be mainly carbon with a platinum catalyst. Furthermore, if the electrochemical cell is a ‘bio-batter’ (which is actually a bio-fuel cell) the anode could be an enzyme providing the catalytic ‘function’. Ultimately, organic catalysts could be used as anodes in fuel-cells of this type.

Normally reduced conjugated polymers such as polyterthiophen or poly-3-methyl-thiophene may also be suitable for use as an anode in the electrochemical cell of the present invention.

The combination of an anode and en electrode comprising an ICP may provide a higher electromotive output than the use of an ICP for both the anode and cathode. Without wishing to be bound by theory, it is likely that certain metals such as magnesium, when used as an anode may cause the ICP to remain in a partly oxidised state, thus maintaining sufficient conductivity to wont as cathode.

### Electrode (Conducting Polymer Cathode)

### (i) Porous Organic Material

Preferably the porous material comprises an organic polymer, it is important that the porous material acts as a barrier between the electrolyte on one side of the material and the air/oxygen on the other side of the material. The person skilled in the art will appreciate that this may be achieved by careful control of the pore size and/or hydrophobicity of the material.

The porous organic material typically based on polypropylene, polyvinylidene fluoride (PVDF) or polyethylene polymers although in some applications cellulosic polymers, such as paper, may be suitable. In it particularly preferred embodiment the porous material is chosen from Goretex®, CelGard®K880, Nafion® or a PVDF membrane such as those marketed by Millipore. Goretex® in a material comprising a microstructure of node and fibrils of polytetrafluoroethylene and described in U.S. Pat. No. 3,953,566. Goretex® has 1.4 billion pores per cm². CelGard® K880 is a polyethylene membrane having similar pore size and structure to Goretex. The Millipore PVDF membrane has significantly smaller pores. Nafion® is a proton conducting membrane composed of sulfonated tetrafluoroethylene based fluoropolymer-copolymer.

### (ii) Inherently Conducting Polymer

The use of ICPs in their pure state for catalytic electrodes has had limited success, mostly due to tow efficiency and Instability of the ICP in the environment required for the catalysis. Attempts have been made to overcome these drawbacks by incorporation of traditional metal catalysts like e.g. Pt or Co into ICPs. However, the stability of these composite materials is limited due to the lack of bonding between the ICP and the catalyst.

ICPs can be divided Into two general classes namely (1) charge transfer complexes and (2) conductive polymers Including polyacetylenes, polypyrroles, polythiophenes, polyanilines, polyfluorenes, poly(3-hexylthiophene), polynaphthalenes, poly(3,4-ethylenedioxythiophene), poly(p-phenylene sulphide), poly(para-phenylenevinylenes) and their derivatives. In a particularly preferred embodiment the conductive polymer cathode is chosen from class (2). A cathode comprising a polymer in the oxidised state (polaron conductivity) is preferable; a polymer in the reduced state (exhibiting semi-conductor behaviour) typically has higher resistance which may overly limit the performance of the battery of the present invention.

It will be readily apparent to the person skilled in the art that the choice of ICP will depend on the nature of the cell. For example, polypyrroles and polythiophenes have a tendency to degrade (n some environments. The suitability of an ICP for a particular application can typically be gauged by using cyclic voltammetry. For example, cyclic voltammetry Indicates that polyacetylenes lend to have an optimal range of capacitance for reducing 07 at a required voltage. In a particularly preferred embodiment, the ICP is a polypyrrole or poly(3,4-ethylenedioxythiophene) (PEDOT). Synthesis of ICP's Including PEDOT by base inhibited oxidative polymerisation of thiophenes and anilines using Fe(III) salts has been previously described in WO 2005/103109. Other preferred embodiments of the ICP include derivatives of PEDOT. Changes in the basic PEDOT structure by relatively simple substitutions may change the ICP properties. For example a substituted PEDOT (Formula I) and ProDOT (Formula II) may be suitable for use with the electrode of the present invention.

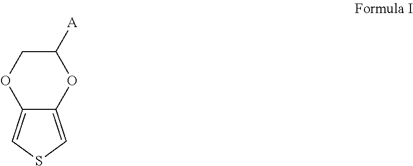

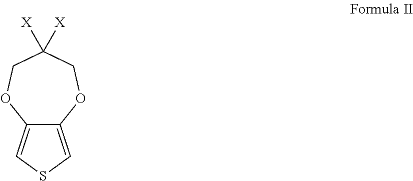

Substituent ‘A’ of Formula I can Include a wide range of moieties, but preferably the substituent Increases the hydrophilicity of the molecule and any polymer formed there from without compromising the conjugation of the polymer. For example. ‘A’ may constitute an alkane chain linking PEDOT and OH (PEDOT-(CH₂)ₙ—OH, where n is typically between 0 and about 12. Alternatively, ‘A’ may for example comprise COH, or a moiety comprising a glycol oligomer such as (PEDOT-(C)ₚ—(O(CH₂)ₘ)ₙ—X, where typically m and p can be 1 to 4, n can be 0 to about 12 and X can be OH, OCH₃, OOH, COOH, COONa. SO₃Na.

In yet another alternative, the PEDOT may be substituted in both position 3 and 4 of the dioxy ring, (e.g. HO—(CH2)ₘ-PEDOT-(CH2)ₙ—OH, where n and m may be the same or different.

The two substituents “X” of Formula II may be the same or different and can include a wide range of moieties. Preferably, each substituent X is independently chosen from the group comprising halides, H, alkanes, aroma tics, ethers, aldehydes, carboxylic acids. In a particularly preferred embodiment each substituent X is independently chosen from the group comprising halides, H, CH₃, C₆H₅ and OCH₃.

When choosing an optimal ICP for use in an electrode, consideration must be given to the nature of the ICP. For example it is anticipated that in accordance with their order of decreasing hydrophilicity, the PEDOT-COH, PEDOT and ProDOT ICPs will perform in the order PEDOT-COH>PEDOT>ProDOT irrespective of the fact that PEDOT-COH has a conductivity that is only about 1% of the conductivity of PEDOT. Furthermore, it must be kept in mind that PEDOT-COH is unstable in alkaline solutions, thus limiting its range of application to electrochemical cells having neutral and acidic electrolytes.

The electrode of the present invention may contain one or more ICPs. For example, the electrode may include two or more ICPs in a physical mixture or a layered structure or an interpenetrating network. Furthermore, the ICP for use in the present invention may comprise one or more ICPs in combination with one or more non-conducting polymers. The combination of non-conducting polymer and ICP may provide characteristics that are preferable to the characteristics of the ICP alone. For example, a non-conducting polymer based on polyethylene glycol (PEG) may be added to provide improved hydrophilicity, phase interface, current density or theological characteristics compared with the pure ICP.

### Combination of Porous Organic Material and ICP

The porous organic material and ICP of the present invention may be combined in any convenient manner. For example, the electrode may comprise ICP coated on the porous organic material. The ICP may be applied in the form of a solid, liquid or gel.

In a particularly preferred embodiment the electrode of the electrochemical cell of the present invention comprises an air/Goretex®/PEDOT cathode or O₂/Goretex®/PEDOT cathode. O₂ from the air may pass freely through the pores of the Goretex® to the PEDOT layer where the PEDOT acts as a high rate oxygen reduction catalyst to reduce the O₂.

A cell having an air/Goretex®/PEDOT cathode and magnesium anode has demonstrated continues operation for 3 weeks without degradation or deterioration of performance. PEDOT also has the advantage of being stable over a wide pH range (pH 0 to 14). The PEDOT appears to cycle its oxidation state during the oxygen reduction reaction. This has been demonstrated in two different modes (1) as an electrode operating at ambient pressure and (2) as a dissolved oxygen electrode operating in aqueous solutions.

Without wishing to be bound by theory it is postulated that the PEDOT Initially is partly reduced before the reduction of oxygen starts (re-oxidising the PEDOT). This leads to an equilibrium (for a given potential) where reduction of oxygen is balancing the re-oxidation of PEDOT.

### Current Collector

In order to improve the electrical conductivity of the ICP to provide a low-resistance path to an external circuit a more electronically conductive ‘current collector’ layer may be used between the ICP layer and the porous organic material. Typically the current collector comprises a thin layer of a conductor coated on one surface of the porous polymer material.

Typically the current collector comprises one or more elements in atomic form, including alloys or layers of elements. The current collector chosen must be compatible with its environment. For example, the current collector must be compatible with the electrolyte of the electrochemical cell and, if the cell is intended tit use in a biological system the current collector is preferably bio-compatible.

In a particularly preferred embodiment the conductor is a metal of generally low reactivity such as Au or Ti. Other metals such as Cu, Ag and Ni are suitable for use as current collectors, but have a higher tendency to react with electrolytes comprising metal salts. The person skilled in the art will appreciate that metals are not the only materials suitable for use as a current collector and certain non-metals such as carbon are suitable. The carbon layer may comprise any suitable form such as nanostructures such as carbon ion tubes, ribbons or sheets.

### Method of Construction of the Cathode

In a particularly preferred embodiment the electrode of the present invention comprises porous material coated on one side by an ICP. By virtue of the pores in the material, the ICP, electrolyte and air are in a close three-phase contact on the μm scale.

The ICP may be applied to the porous material by any convenient method, such as, for example vapour phase polymerisation or plasma-polymerisation such as, for example, low power AC plasma-polymerisation. Good control over the thickness of the applied layers is necessary in order to avoid any blocking of the pores in the porous material.

Alternatively, the ICP may be incorporated into the structure of the porous material.

### Encapsulating Means

The encapsulating means may be constructed of any convenient material. When the electrochemical cell is a battery, the principal purpose of the encapsulating means is to contain the aqueous electrolyte intermediate the metal anode and conducting polymer cathode. When the battery is intended for in vivo use it also forms a barrier between the components of the battery and living tissue so at least the outermost part of the encapsulating means is preferably constructed of bio-compatible material. In a preferred embodiment the entire electrochemical cell is made of bio-compatible, bio-degradable material and the encapsulating means is the first component of the battery to degrade. When the electrochemical cell is a fuel cell, the encapsulating material will be adapted to allow inflow of reactant and outflow of reaction products.

### Integration

The electrochemical cell of the present invention may be in the form of a fuel-cell. Typically this is achieved by integrating the cathode with an ion-conducting membrane of the type used in fuel cells. Membranes made of material such as Nafion® are often used in proton exchange membrane fuel cells (PEMFC) due to their capabilities as proton conductors and because they often have excellent thermal and mechanical stability. The ion-conducting membrane can either be laminated to the air-electrode as normally used with conventional Pt-based air-electrodes or the ion-conducting membrane can be coated directly on the ICP based air-electrode from a solution or by any other means suitable.

### Other Features

The electrochemical cell according to the present invention may comprise a battery that provides a direct current (DC). However by combining two batteries appropriately wired, and switching between the two, it is possible to provide an alternating current (AC). This would be particularly advantageous for many in-vivo applications where the use of DC causes damaged caused by electrophoresis

In another preferred embodiment the electrochemical cell of the present invention can be switched on and off using a magnetic switch. This would be particularly advantageous for in vivo applications so that the electrochemical cell can be activated and turned off by a magnetic switch located outside the body.

### EXAMPLES

The present invention will be further Illustrated with reference to the following non-limiting examples.

### Example 1

### PEDOT on Goretex

One embodiment of an electrode for the con of the present invention is depicted schematically in FIG. 1(a). The electrode was then included in an electrochemical cell of the type depicted at FIG. 2(e) and used in a series of experiments to characterise the present invention and compare its performance with more conventional constructions in some of the experiments the electrode also includes a thin layer (approx. 20 nm) of gold between the ICP and Goretex, the gold acting as a conductor. The results of these tests are depicted in FIGS. 3 to 10. The electrolyte used for each test is as specified below.

The electrode as depleted in FIG. 1 allows access of the air stream from one side of the electrode to a high-surface area electrochemically active layer of ICP which is simultaneously in contact with electrolyte. The structure of the underlying porous material is visible in the electrode indicating that a three-phase boundary interface is obtained over a substantial fraction of the membrane. Optimally the porous material provides a membrane that is highly porous at the micrometer level and being hydrophobic, does not allow penetration of the aqueous electrolyte into the pores of the membrane.

If the electrical conductivity of the ICP is low a more electronically conductive layer (current conductor) can be used between the ICP and porous material. For example. It has been found that a layer of gold of about 40 nm thickness can be used without altering the structure of a Goretex membrane when used as the porous material.

Many of the following examples utilised an electrode that was constructed by coating PEDOT onto one side of a sheet of Goretex (commercially available from Gore Inc.) using the method depicted in FIG. 2. This process provides a plasma-polymerised poly-acid layer on one side of the Goretex that provides good bonding to the PTFE and ensures that the oxidant (Fe(III)PTS) stays on that side, with the PEDOT only polymerised on one side during the vapour phase polymerisation (VPP).

Specifically, an acid monomer such as maleic anhydride is plasma polymerised on one side of the Goretex using a low power AC plasma discharge operating in a plasma chamber. The plasma parameters were tuned to ensure good binding between the plasma-polymer and the Goretex substrate. For electrodes including a metallic current conductor, the plasma chamber may be further equipped with a magnetron working as a sputter unit allowing the plasma polymerised material and sputtered layer to be applied in the same chamber. An oxidant for the polymerisation, iron(III) para-toluenesulfonate (Fe(III) PTS) obtained from H. C. Starck in a 40% solution. In butanol, was then applied to the polyacid. Vapour phase polymerisation of the conducting polymer was than carried out. Once the polymerisation was complete, the Fe(II) and excess of anion was washed out with ethanol. The layer of PEDOT was typically about 400 nm thick (equivalent to about 0.05 mg/cm²) but for other embodiments the optimal thickness will change with pore size, shape and other characteristics of the porous material. When a current conductor was included in the electrode the layer thickness was optimised to give the desired surface resistance on the PTFE membrane. For example, the optimal surface resistance was between 12 and 15 Ohm/sq.

The person skilled in the art will readily appreciate that this method can be adapted for use with other monomers and oxidants, depending on the ICP desired. For example, the use of maleic anhydride is not essential for the construction and other monomers are suitable for use in the method. However, good control over the thickness of the applied layers is necessary, particularly to avoid any blockage of the pores in the porous material. Furthermore, low-power AC plasma-polymerisation and VPP are only two of the many potentially useful polymerisation techniques.

### Example 2

### PEDOT on Goretex in an H₂/O₂ Fuel Cell

The PEDOT-Au-Goretex electrode described above was also used in a hydrogen/oxygen fuel cell comprising a Nafion polymer membrane. The electrode was used to replace the usual carbon/Pt cathode in the cell construction, so the carbon/Pt anode for hydrogen oxidation and the proton-conducting polymer membrane (Nafion®) was unchanged. The cell was placed in a graphite setup, ensuring good electrical and thermal contact. The humidity and the temperature of the cell were controlled during the test.

This fuel cell was used to generate the plot shown as FIG. 10 below. The discharge current was stepped up to 100□A/cm² and the voltage measured over time, while hydrogen and oxygen was supplied to the cell with constant flow-rates.

### Example 3

### Example 3(a)

### PEDOT on Au and Au/Pt Coated Goretex

A PEDOT Au-Goretex electrode Was compared with a PEDOT-Au/Pt-Goretex electrode at different pH values. The latter was created by sputtering a 45 nm Pt layer onto the Au layer. The thickness of the Pt was measured on a glass slide exposed to same Pt sputter procedure.

The magnitudes of the conversion currents delivered by the PEDOT electrode are comparable to those of Pt for the same geometrical area of porous material. However, as seen in FIGS. 4(a) to 4(c), at low pH the platinum based electrode is more efficient whereas at higher pH the conversion currents are similar. Most proton conducting polymer membrane fuel-cells are operated at low pH.

Although the thicknesses are different for the Pt (45 nm) and PEDOT (400 nm) layers the differences in their densities (21.1 g/cm³ for Pt and approx 1.2 g/cm³ for PEDOT) means that the mass loading of active material is actually lower in the PEDOT case by a factor of about 2.

### Example 3(b)

### Long Term Performance

Long term performance for the PEDOT-Au-Goretex electrode at −300 mV vs SCE was studied in 1M H₂SO₄ electrolyte (pH 1) over 66 days (see FIGS. 11(a) and 11(b)). The measured value (in mA/cm²) has been converted into conversion current per gram of PEDOT in the cell. In FIG. 11(b) the steady state measurement as a function of potential measured before the long-term test is compared to a measurement after 51 days. It can be seen that the conversion current for the oxygen reduction is slightly increasing (upper line) over the test period, proving a very stable and durable system.

### Example 3(c)

### Susceptibility to CO Poisoning

One of the main concerns when using metal-based electro-catalysts such as platinum is the potential risk for poisoning with CO, blocking the active sites on the catalyst and thereby decreasing performance of the electrodes. FIG. 12 compares the performance of the PEDOT and Pt based electrodes for different levels of CO contamination in the air supply. In FIG. 12(a) PEDOT and Pt based air-electrodes are compared when 10% CO is added to the feeding gas (air) at time=0. The performance of the platinum electrode decreases dramatically, whereas the PEDOT based electrode seems unaffected by the CO. FIG. 12(b) shows the almost linear relationship between conversion current and oxygen contents in the feeding gas, proving that gas diffusion through the membrane is not limiting the performance. In summary the PEDOT electrode was not affected by the presence of CO contamination in the air supply whereas the Pt electrode was poisoned very rapidly under identical conditions. The formation of carbonyl complexes of Pt at the surface that poison the metal's activity is unlikely with PEDOT. The effect of oxygen partial pressure in the gas supply (air=20%) (FIG. 12(b)) demonstrates that the electrode is capable of even higher currents than are generated in air and that no limit related to processes within the PEDOT is reached over the range of oxygen contents probed.

### Example 4

### PEDOT-Ti-Goretex

A PEDOT-Ti-Goretex electrode was made by evaporating titanium onto the Goretex membrane. The resistance for the Ti layer was 18 ohm/square-0.33% higher than for the gold layer. Thicker Ti layers tended to block the pores in the Goretex membrane indicating that a membrane with larger pore-size may be better in order to use thicker Ti layers and thereby decrease the ohmic resistance. Electrodes with the Ti current collector coated with PEDOT were tested under identical conditions as described above and current densities of 1.2 mA/cm2 was measured at −300 mV vs. SCE over 7 days. This value is lower than what was obtained for the PEDOT-Au-Goretex electrode reflecting the higher resistance of the Ti coating.

### Example 5

### CelGard K880 and Millipore PVDF Membranes

A polyethylene (PE) CelGard K880 membrane (which has a similar structure to Goretex in terms of pore-size and shape) was used to test the viability of porous materials other than PTFE membrane.

Example 1 (above) outlines a preferred method for constructing an electrode cell of the present invention, that is, by polymerising an acid monomer such as maleic anhydride on one side of a Goretex membrane, then applying an oxidant for the polymerisation, Fe(III)PTS, to the polyacid. Upon completion of the polymerisation, the Fe(II) and excess of anion is washed out with ethanol.

For the purpose of applying the ICP (PEDOT-PTS and PEDOT-CI) an alternate route using Fe(III) solution was developed. Specifically, when ethanol or butanol is used as a solvent the PE membrane is entirely wetted, thus preventing the preferred “only-one-side” coating. Changing the solvent to a water-ethanol mixture (3:1) created the surface tension required to wet the surface of the membrane without wetting through the membrane. Drying of the Fe(III), vapour phase polymerisation and the testing was done as described above for the PTFE membrane.

For both PEDOT-PTS and PEDOT-CI current densities in the 1.5 to 2 mA/cm² (in 1M H₂SO₄ at −300 mV vs. SCE) range was achieved, which is equivalent to the range achieved for the Goretex membrane was observed. Long-term testing of the CelGard K880 membrane with PEDOT-CI over 30 days (In 1M H₂SO₄ at −300 mV vs. SCE) showed only very minor decay in the current density. This decay may be due to the acidic conditions causing the PE membrane to slowly collapse indicating that the Membrane material has to be designed with the end-use in mind, not the procedure for coating the conducting polymer.

Similarly a PVDF membrane (Millipore) with smaller pore-size (0.45 μm) was tested however the small pores were easily clocked by the PEDOT, resulting in collapse of the three-phase interface and concomitant poor current density during oxygen reduction tests.

### Example 6

### Alternative Oxidant for Forming the Electrode

In Examples 1 and 5, Fe(III) PTS is described for applying the ICP to a porous organic material. Fe(III)CI is much cheaper than Fe(III) PTS, but it has not hitherto been possible to obtain smooth and homogeneous coatings when using Fe(III)CI as oxidant for polymerisation of conducting polymers. As described in Example 5, coating onto PE and PVDF membranes without coating through them forced a change in solvent for the Fe(III) solution from the traditional alcohol based to a mainly water-based system. By adding a small amount of additives to the solution in form of oligo-polyurethanes, poly-ethyleneglycol (PEG) or similar hydrophilic molecules it was possible to obtain smooth films of the dried Fe(III)CI and the subsequent vapour phase polymerisation also produced PEDOT film with good smoothness. When studied in the scanning electron microscope (SEM) it was found that these PEDOT-CI coatings are nano-structured. Controlling the nano-structure of the PEDOT material itself can have big advantages in order to increase active surface area and minimize diffusion limitations in the material. The properties of the nano-structure (such as size and hydrophilicity) can be varied by changing the kind and amount of additives.

The resistance of the PEDOT-CI coating was measured on glass substrates and the conductivity calculated after thickness measurements using a Dektak profilometer. Conductivities of 300 S/cm was obtained for the PEDOT-CI films. These values can be compared to the 1000 S/cm normally obtained using Fe(III) PTS and 30-60 S/cm for conventional PEDOT-CI film form organic solvents. The PEDOT-CI film on Goretex-Au was tested as air-electrodes according to our normal procedure and performance similar to the PEDOT-PTS was observed—already being a cost-efficient alternative to the PEDOT-PTS. However, the potential of tuning the nano-structure of the PEDOT-CI material has not yet been explored and it is anticipated that this can further improve the performance of the PEDOT-CI material.

### Example 7

### Composites of Conducting and Non-Conducting Polymers

PEDOT was combined with poly ethylene glycol (PEG) to investigate the effectiveness of the combination for the purposes of the present invention. A mixture of PEDOT and PEG in a 1 to 1 ratio is more hydrophilic than PEDOT alone. Furthermore, the mixture exhibits an enhanced three-phase interface and gives 50% higher current densities than pure PEDOT in acidic electrolytes.

The conducting polymer can be mixed with PEDOT by simply adding a solution of the polymer to the Fe(III) solution, before vapour phase polymerisation and using a non-solvent for washing out Fe(II) and excess PTS after the polymerisation. Several polymers and oligomers can be mixed into the PEDOT matrix using this procedure. This includes PEG, poly-propyleneglycol (PPG) (and co-polymers of these), poly-urethane, poly-vinyl-acetate (and co-polymers of this with e.g. PE), poly-acrylates (as long as their side chains don't react with Fe(III)) and other polymers that can be dissolved in solvents that can dissolve Fe(III) salts.

### Example 8

### Comparison of ProDOT, Dimethyl-ProDOT and PEDOT

The performance of ProDOT, di-methyl-ProDOT and PEDOT in electrodes under identical conditions was compared. PEDOT performed significantly better than the more hydrophobic ProDOT and di-methyl-ProDOT. The more hydrophilic PEDOT-COH showed superior performance to PEDOT. This is despite that the conductivity of PEDOT-COH only is 3 S/cm or less than 1% of PEDOT-PTS. For PEDOT-001-1-PTS conversion currents of 3.5 mA/cm² on Goretex —Au Membranes is routinely achieved, compared to the best values for pure PEDOT-PTS of 2 mA/cm² (both at −300 mV vs. SCE in 1M H₂SO₄). The long-term stability of PEDOT-COH as air-electrode was tested over 30 days (at −300 mV vs. SCE in 1M H₂SO₄) without any sign of decay. However it should be mentioned that PEDOT-COH is unstable under alkaline conditions, limiting the use of this material for most metal-air batteries.

Polypyrrole was also tested as an electro-catalyst for oxygen reduction. The polypyrrole was coated onto a Goretex-AU membrane and tested similarly to the PEDOT based electrodes. Conversion currents around 1 mA/cm² were obtained at −300 mV vs. SCE in 1M H₂SO₄, but the polypyrrole electrode showed poor stability, only lasting for few hours. However this example, shows that the phenomena of electro-catalysis is not limited to PEDOT and that it is actually possible to tune/change the electro-catalytic properties of the ICP by relative small changes in polymer structure.

### Example 9

### Mechanism

In order to investigate the mechanism of the process taking place in the PEDOT-Goretex electrode of the present invention, the electronic conductivity (σ) of a the electrode was measured against potential Ewe (V) using an aqueous system including an 0.1M phosphate buffer at pH 7 (FIG. 13). PEDOT in the absence of oxygen adopts a variable state of oxidation as a function of potential between about −0:5 to −0.5V versus Ag/AgCI in aqueous solution. It is transformed from a low-conductivity material in its reduced state to a highly conductive material in its fully oxidized state. Operating the PEDOT-Goretex electrode at various potentials shows a conductivity profile with much higher conductivity at lower potentials (FIG. 13) compared to PEDOT in the absence of air, indicating that the PEDOT is reaching a steady-state oxidation level according at the applied potential which is greater in the presence of air. Without wishing to be bound by theory, this supports the hypothesis that the mechanism for the air reduction electrocatalysis likely involves a redox cycling process where the PEDOT, which naturally rests in an oxidized form, is momentarily reduced by the action of the electrochemical cell. An oxygen molecule then absorbs onto the surface of the PEDOT and rapidly reoxidizes the PEDOT to its preferred oxidized state and is itself reduced Int the process.

### Example 10

Goretex-based electrodes were tested in a Zn-air battery using a similar setup as for the electrochemical testing described above. 1M KOH was used as electrolyte and the anode comprised a Zn rod. FIG. 14(a) shows steady state measurements (after 12 hours) of the discharge voltage for two different electrodes as function of discharge current. The discharge voltage was higher for PEDOT-Goretex than for the Pt-Goretex electrode. This is also the case for longer-term discharge experiments. For example FIG. 14(b) shows the first 48 hours of a discharge at 1 mA/cm² for Pt and PEDOT electrodes, where the PEDOT electrode shows a much more stable performance at a higher discharge voltage.

### FIGURES

Various embodiments/aspects of the Invention will now be described with reference to the following drawings in which;

FIG. 1(a) is a schematic drawing in cross section of the electrode described at Example 1 and FIG. 1(b) is a schematic drawing of an electrochemical cell including the electrode of FIG. 1(a),

FIG. 2 is a flow chart illustrating one embodiment of the method of construction of the electrode,

FIG. 3 are plots of current I (mA/cm²) against potential Ewe (my) which allow comparison of prior art oxygen reduction electrodes (platinum, polythiophene and platinum particles in polythiophene) with the electrode of the present invention,

FIG. 4 is a plot of current I (mA/cm²) against potential Ewe (V) illustrating oxygen reduction conversion currents measured at different pH values,

FIG. 5 is a plot of current 1 (mA/cm²) against pH showing the pH dependency of the conversion current for oxygen reduction of PEDOT on Au on Goretex,

FIG. 6 is a plot if potential Ewe I (μA) against O₂ content in the gas mixture for the electrode of the battery of Example 1,

FIG. 7 is a plot of potential Ewe (V) against time (days) showing the discharge voltage of the battery of Example 1,

FIG. 8 is a plot of potential Ewe (V) against time (hours) showing performance of the battery of Example 1 with water instead of air,

FIG. 9 is a plot of potential Ewe (V) and J (μA/cm²) against time (hours) for the battery of Example 1 having a solid LICI/PEO electrolyte for the fuel cell of Example 2.

FIG. 10 is a plot of potential Ewe (V) against time (hours) for the fuel cell of Example 2.

FIG. 11(a) is a plot of current density (I(A/g)) against time (days) and FIG. 11(b) is a plot of conversion current (I(mA/cm²)) against potential (Ewe (V)) for the electrodes of Example 3.

FIG. 12(a) is a plot of current (I(mA/cm²)) versus time in air contaminated by 10% CO and FIG. 12(b) is a plot of current (I(mA/cm²)) as a function of % oxygen content in the gas supply for the electrodes of Example 3.

FIG. 13 is depicts the electronic conductivity (σ) of a PEDOT-Goretex membrane against potential Ewe (V) in 0.1M phosphate buffer at pH 1.

FIG. 14 relates to a Zn air battery comprising (i) a PEDOT-Au-Goretex electrode and (ii) a Pt/Au-Goretex electrode wherein FIG. 14(a) is a plot of discharge potential Ewe (V) against discharge current (I_{dis}(mA/cm²)) and FIG. 14(b) is a plot of the discharge current (I_{dis}(mA/cm²)) against time over 48 hours.

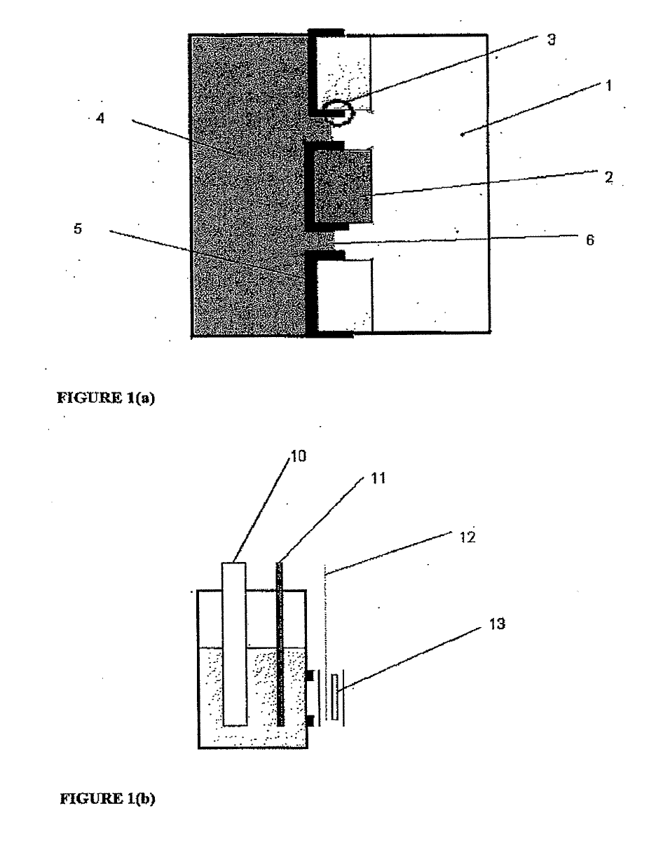

### FIG. 1

FIG. 1(a) is a schematic drawing of the electrode (cross-section) described in Example 1. In this drawing the porous membrane (2) coated with current collector (6) and ICP (5) can be clearly seen. Air (1) and an electrolyte (4) are on either side of the membrane/ICP/current collector. The hydrophobic nature of the porous membrane prevents the electrolyte from wetting through the membrane. At the same time, the structure allows contact of the electrolyte, current collector, ICP and air (see for example the area within the circle).

FIG. 1(b) is a schematic drawing of an electrochemical cell of the type used for the testing carried out in the examples. In this drawing the reference electrode (10), platinum counter (11), gold connector (12) and electrode (13) of FIG. 1(a) can be clearly seen. The ICP, porous material is sandwiched with a gold electrode using conventional office laminating techniques. A 1×1 cm² window in the laminate allows access for air from the bare side of, the porous material and for electrolyte from the ICP coated side when mounted on the test cell. Phosphate buffer electrolytes were Used to maintain pal values.

For measuring the resistance of the ICP during operation (to calculate the electronic conductivity) a special laminated layout was used. Here a 0.5×1 cm² window was used, the porous material membrane was cut to a 0.6×2 cm² and two gold connectors were connect to each end of the membrane. The resistance was measured between these gold connectors. The gold connectors were not in contact with the electrolyte during the measurement.

For the electrochemical testing a multi-channel potentiostat (VMP2 from Princeton Applied Research) was used to apply potential and measure the resulting conversion current. Steady-state measurements of the conversion current were obtained after one hour at the given potential. A saturated calomel reference electrode was used to control potentials; the internal structure of the electrode presents an unknown internal resistance (and hence a potential shift) in these measurements. Potentials have therefore been used for comparison purposes only.

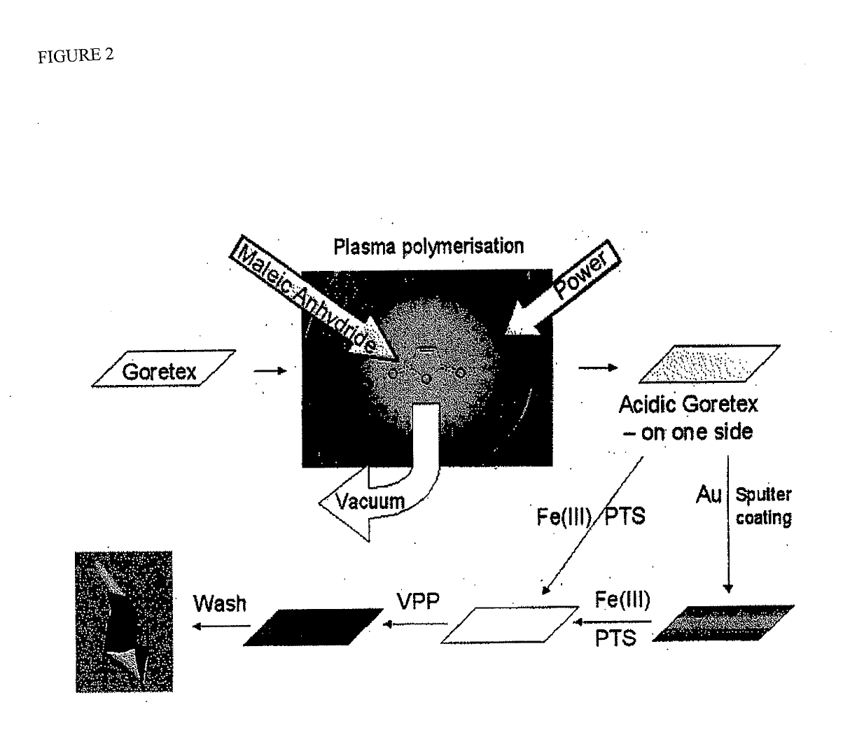

### FIG. 2

FIG. 2 is a flow chart Illustrating one embodiment of the method of construction of the electrode as described above in Example 1 when the ICP is PEDOT.

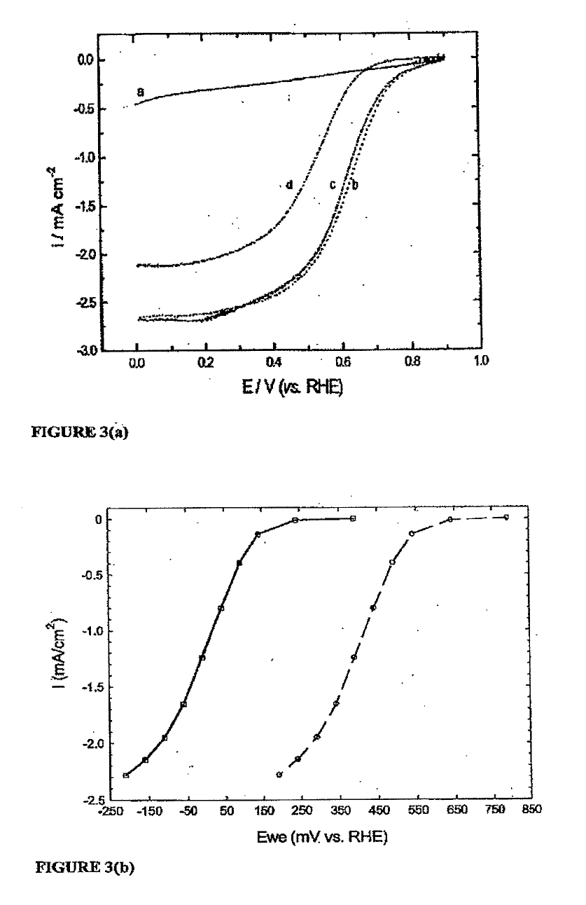

### FIG. 3

FIG. 3 shows a comparison of prior art work on oxygen reduction electrodes (platinum, polythiophene and platinum particles in polythiophene) with the electrode of the present invention as described in Example 1, including a gold coating between the ICP and Goretex. The prior art work is from M. T. Giacomini, E. A. Ticianelli, J. McBreen, M. Balasubramanian, Journal of The Electrochemical Society, 148 (4) A323-A329 (2001). Specifically FIG. 3(a) shows ORR polarization curves at PTh/Pt films (35 growth cycles at 75 mV s⁻¹) on glassy carbon substrate in 2.0 M H₂SO₄ (a) without, platinum particles, (b) 40 cycles, (c) 80 cycles of platinum electroreduction, (d) Pt electrode. The scan rate was 5 mV e carried out at room temperature with w=2500 rpm. FIG. 3(b) shows equivalent results using an electrode as described in Example 1. Specifically it illustrates O₂ conversion on PEDOT of the electrode which is in direct contact with air on the uncoated side of the membrane. The curve at the left hand side of FIG. 3(b) is a steady state measurement in NaPTS at neutral pH on the coated side of the membrane. The curve at the right hand side of FIG. 3(b) shows the measurements converted to pH 0.8. Comparison of FIGS. 3(a) and 3(b) shows that the PEDOT electrode performs similar to or better than the electrodes of Giacomini et al with regard to current density and potential.

The y-axis of the plots is scaled in mA/cm². The maximum value converts to 10 A/g of PEDOT which compares favourably with the prior art values.

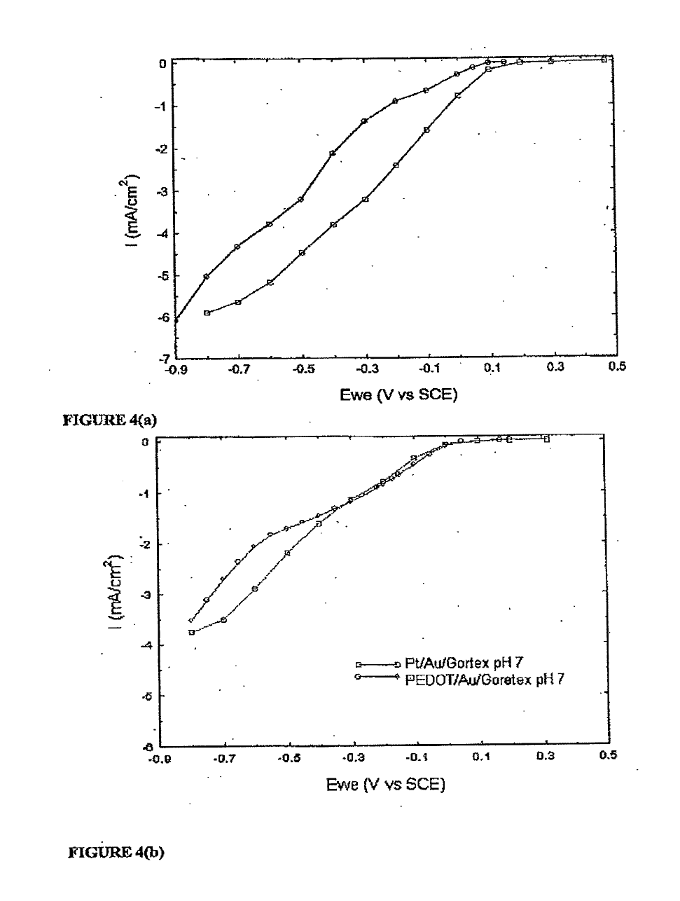

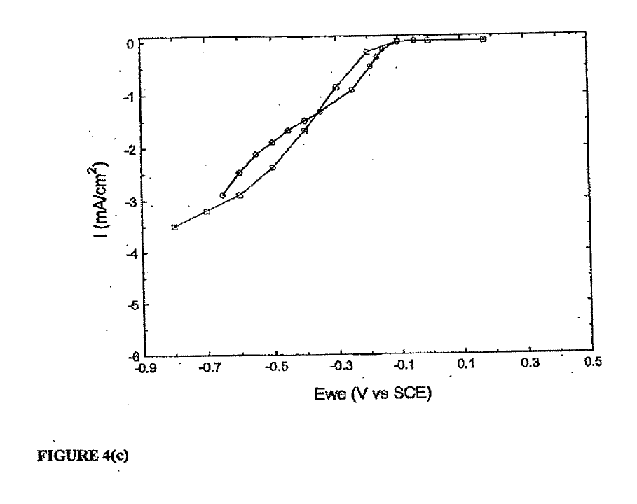

### FIG. 4

To compare the oxygen reduction on the PEDOT electrode directly with a platinum electrode, Pt was sputter-coated onto the Goretex with gold-coating as a direct substitute for the PEDOT and tested under identical conditions. Two different Pt thicknesses Were tested (23 nm and 48 nm) In phosphate buffer, pH 7. The conversion current was 0.81 and 1.08 mA/cm² for the two thicknesses of Pt. Under same conditions a PEDOT electrode gave 1.19 mA/cm². The PEDOT electrode shows a much more distinguished dependency of thickness—suggesting that the whole volume of PEDOT is employed in the conversion, not only the surface. Measuring the precise amount of PEDOT on the electrodes is however not trivial and further work has to be done. When the PEDOT layer becomes thick enough to close the pores in the Goretex membrane the performance of the electrode decreases significantly. This supporting the need for a “three phase” interface, where gas, electrolyte and PEDOT in mutual contact.

The electrode also showed no sign of degradation after 16 days and more than 0.5 Ah/cm² Conversion current (in neutral solution). Long-term tests at different pH and potentials are yet to be fully investigated

FIG. 4 is a plot of (mA/cm²) against E (V) (the oxygen reduction conversion current) measured on the PEDOT/Au/Goretex electrode at different pH (FIG. 4(a): pH 1, 4(b): pH 7 and 4(c): pH 13) values and compared with a similar Pt/Au/Goretex electrode (45 nm Pt). For all pH values the performance of the PEDOT and Pt electrode are quite similar. At pH 7 and pH 13 the PEDOT is shows a steeper increase in conversion current at lower over-potentials. This is indeed in this range a higher current is preferable to limit ohmic loss. For pH 1 the conversion current is lower for PEDOT than for Pt. Especially the offset potential seems to be around 0.1 V lower for PEDOT that for Pt. However, It is worth no notice that even at pH 1 the performance of PEDOT is close to that of Pt.

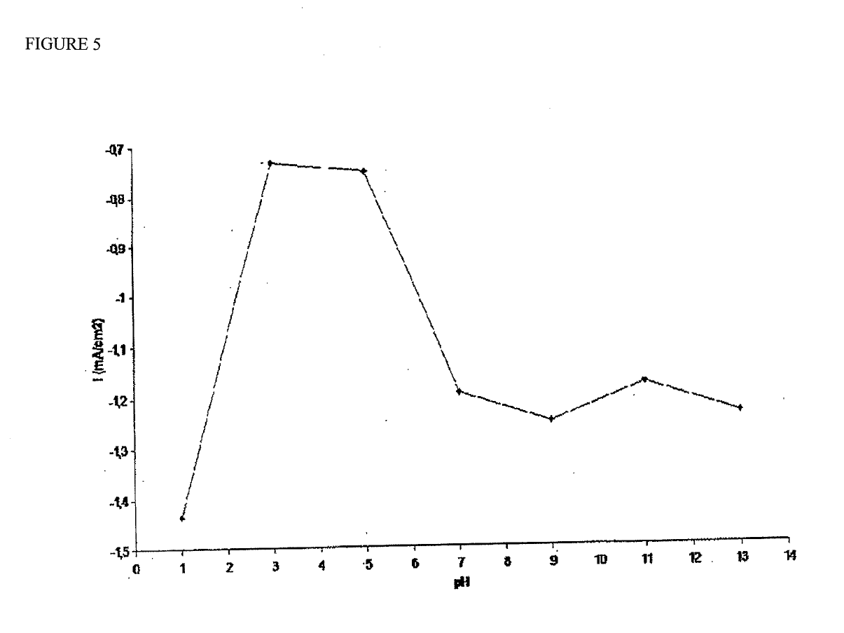

### FIG. 5

FIG. 5 is a plot of I (mA/cm²) against pH showing the pH dependency of the conversion current for oxygen reduction of PEDOT on Au on Goretex (measured after 24 hour at −0.3V vs. SCE). The behaviour is not easily understood and further investigation has to be made to separate the influence of the oxidation/reduction of PEDOT and the oxygen reduction according to the assumed schemes below.

4(PEDOT⁺/PTS⁻)+4e⁻⇄4PEDOT⁰+4PTS⁻

O₂+4H⁺+4e⁻→2H₂O (Acid/Neutral)

O₂+2H₂O+4e⁻→4OH⁻ (Neutral/Basic)

It is well known that the oxidation/reduction equilibrium of PEDOT depends an pH; low pH pushes the equation to the left—and increases the conductivity of PEDOT, but it is not obvious why this should give the dependency seen in FIG. 5. FIG. 5 does however illustrate that PEDOT has a very wide operating window with regard to pH.

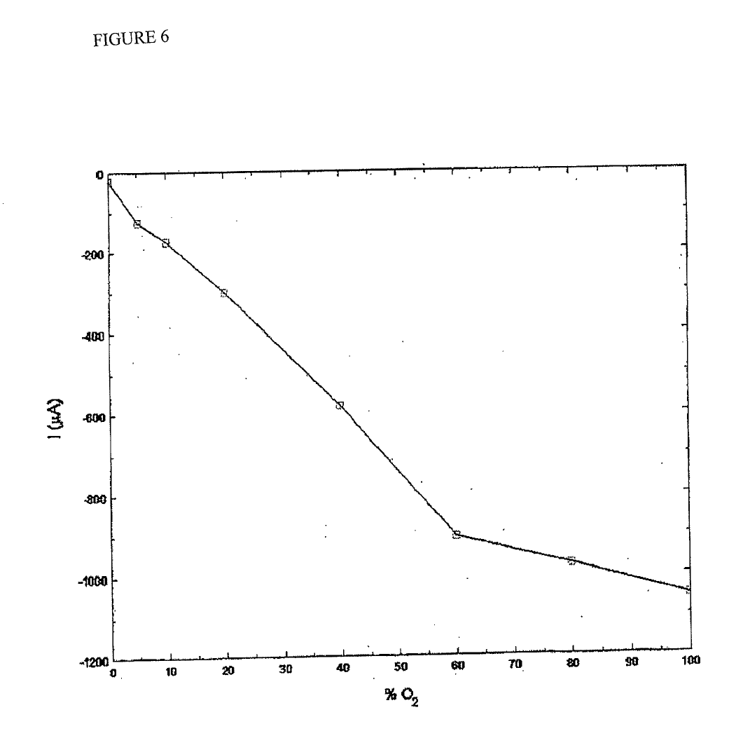

### FIG. 6

FIG. 6 is a plot if I (μA) against O₂ content in the gas mixture for the electrode of the battery of Example 1. Measurements were carried out on the electrode (no Au layer) in 0.5M Na(p-toluenesulphonate) (−0.1V vs Ag/AgCl₂). Steady state measurements were carried out using at gas mixtures having differing O₂ content. The plot shows a quite linear correlation up to about 60% oxygen where presumably diffusion related, limiting reactions becomes significant. The conversion current is dependant on the oxygen content in the applied gas mixture.

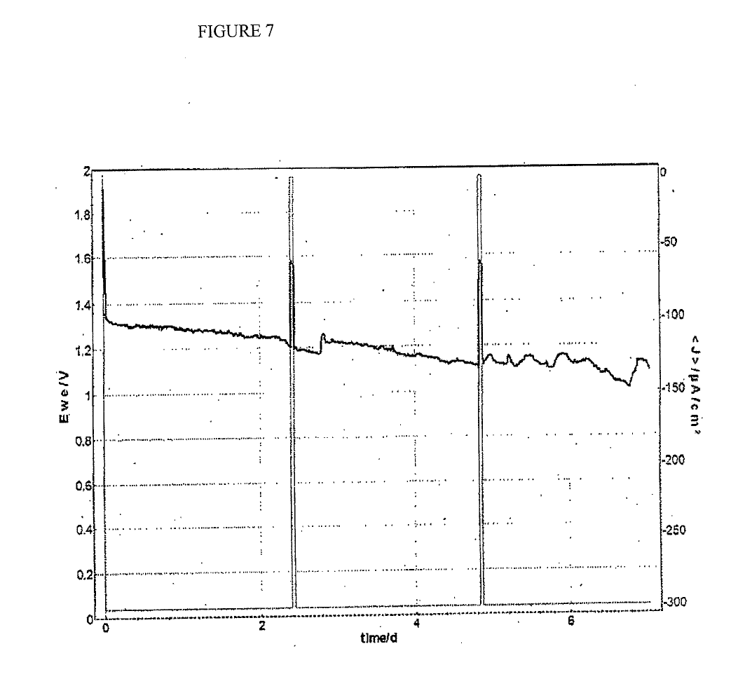

### FIG. 7

FIG. 7 is a plot of Ewe (V) against time (days) showing the discharge voltage of the battery of Example 1 using an electrolyte of 12M LiCl at pH 11.5 at a, discharge current of 300 μA/cm² for one week. The total discharge was 50 mAh/cm² or 700 mAh/g_{Mg}. The drop in voltage is due to increased resistance in the cell caused by oxidation products from the Mg anode. In this case the limiting reaction in the cell occurs at the Mg anode and the build up of oxidation products in the cell that decreases the performance. The PEDOT electrode has successfully been reused in up to 4 cells, and exhibited a durability of more than 8 weeks.

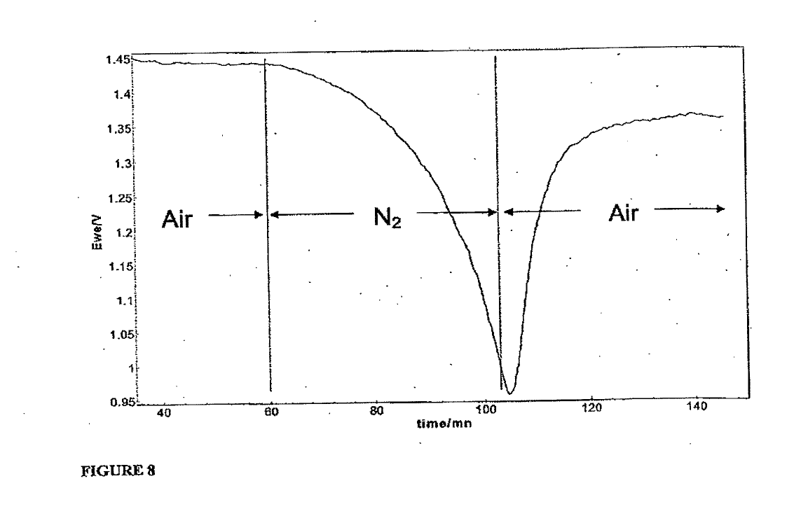

### FIG. 8

FIG. 8 is a plot of Ewe(V) against time (minutes) showing performance of the battery of Example 1 immersed in 200 ml water (0.2M NaNO₂) saturated with N₂ or Air as marked on the plot. The Mg battery in this case comprised an electrodelyte of 12M LICI and the water in 200 ml of 0.2M NaNO₃. When the water is saturated with air the battery performance is similar to the performance in air. However, when N₂ is bubbled through the water the battery performance decreases as the oxygen in the water (and electrolyte) is used or replaced with N₂. Further, when shifted to air bubbling again the battery comes back to ‘normal’ performance. This Illustrates how the O₂ moves from water, across the pores of the porous material into the electrolyte.

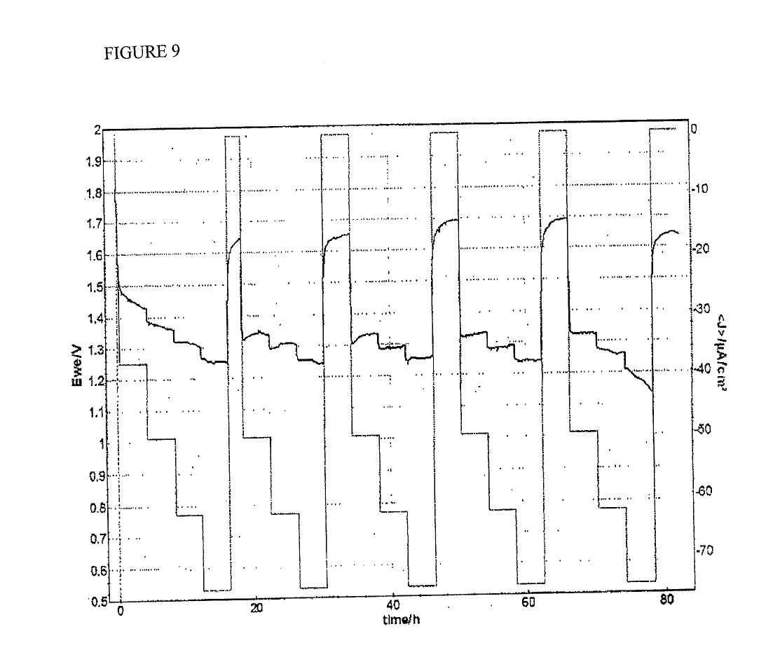

### FIG. 9

FIG. 9 is a plot of Ewe (V) and J (μA/cm²) against time (hours) for the battery of Example 1 having a solid LICI/PEO electrolyte. Specifically, the electrolyte comprised a gel of 9M LICI at pH 11 combined with polyethylene oxide (PEO) in a ratio of 1:1 (w/w). PEO melts at around 50° C. hence it readily incorporates the LICI.

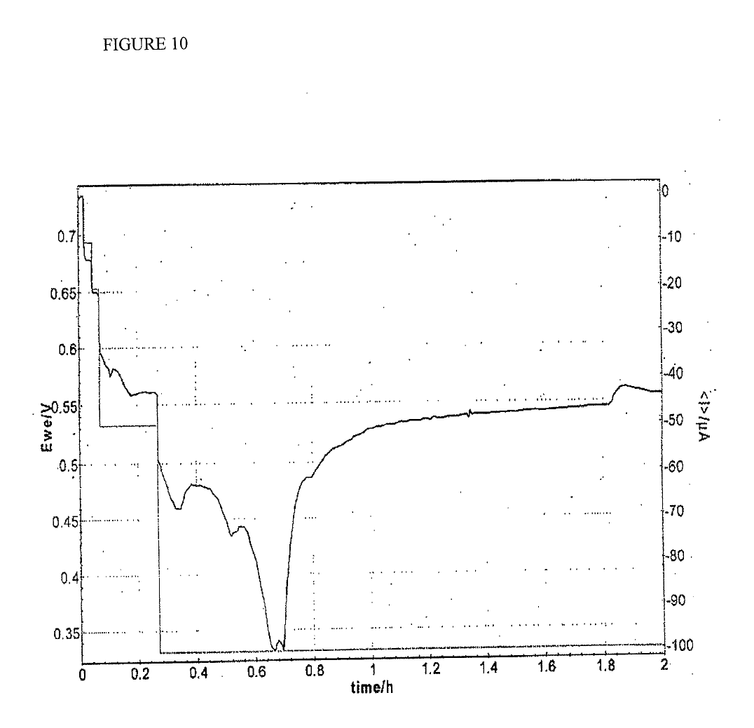

### FIG. 10

FIG. 10 is a plot of Ewe (V) against I (μA) against time (hours) for the fuel cell of Example 2. The main conclusion from this experiment is that the PEDOT oxygen electrode actually works as cathode in the fuel-cell. A major challenge is to adjust the humidity and temperature in the cell to fit both types of electrodes employed in the cell. Optimisation of the active catalytic area, the ionic contact to the proton-conducting etc. would further improve performance of the electrode.

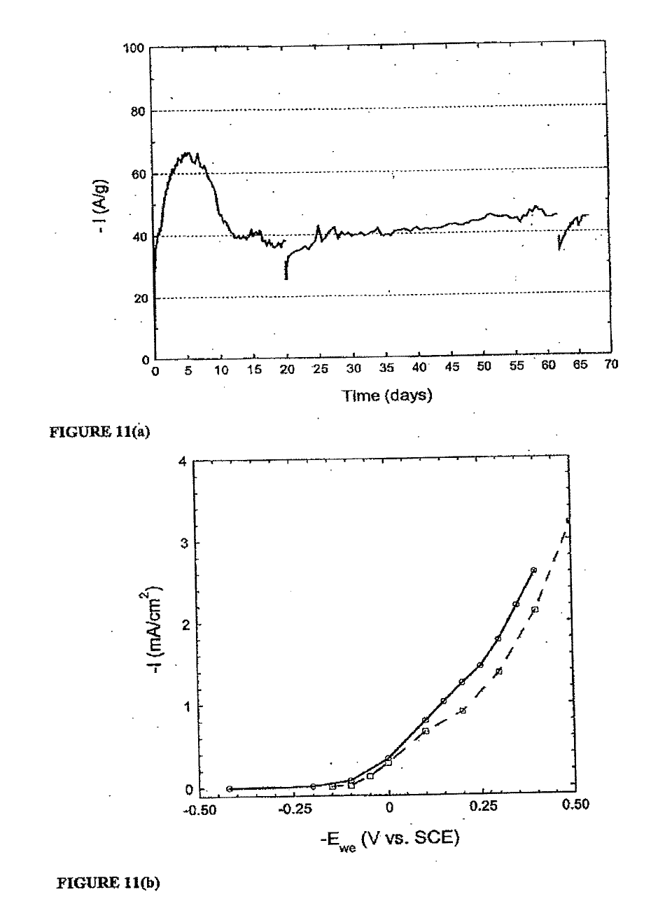

### FIG. 11

FIG. 11 comprises graphs depicting the long term testing results for the electrode of Example 1 operating in 1 M H₂SO₄. Specifically FIG. 11(a) is a graph of current against over 66 days. The measured value (of about mA/cm²) has been converted into conversion current per gram PEDOT in the cell. In FIG. 11(b) is the steady state measurement as function of potential.

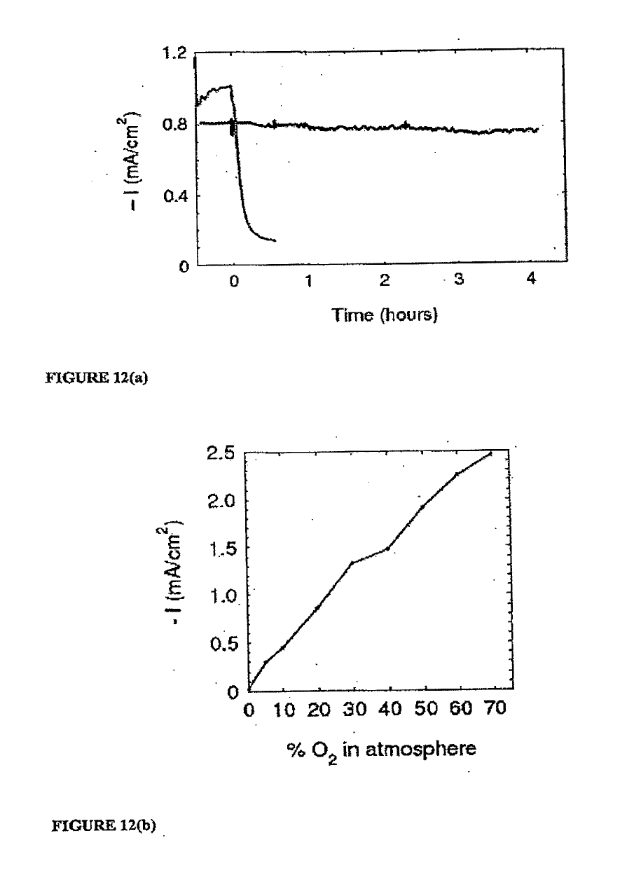

### FIG. 12

FIG. 12 depicts the response of the PEDOT electrode to different gas supplies (−0.3V vs SCE, 0.1M phosphate buffer, pH 7) as described in Example 3: FIG. 12(a) is a plot of current (I(mA/cm²)) versus time in air contaminated by 10% CO and FIG. 12(b) is a plot of current (I(mA/cm²)) as a function of % oxygen content in the gas supply.

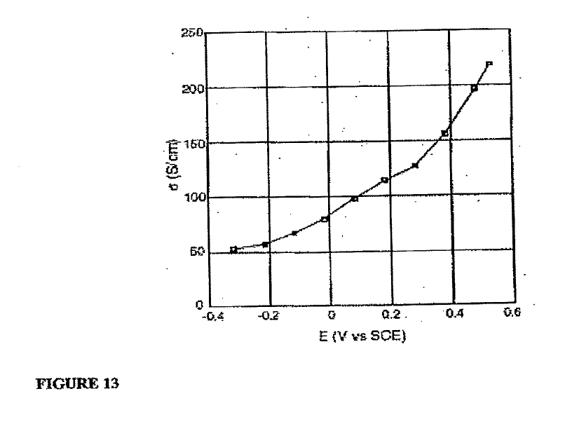

### FIG. 13

FIG. 13 is depicts the electronic conductivity (a) of a PEDOT-Goretex membrane against potential Ewe (V) in 0.1M phosphate buffer at pH 7 to provide some insight into the mechanism of the processes taking place in the electrode.

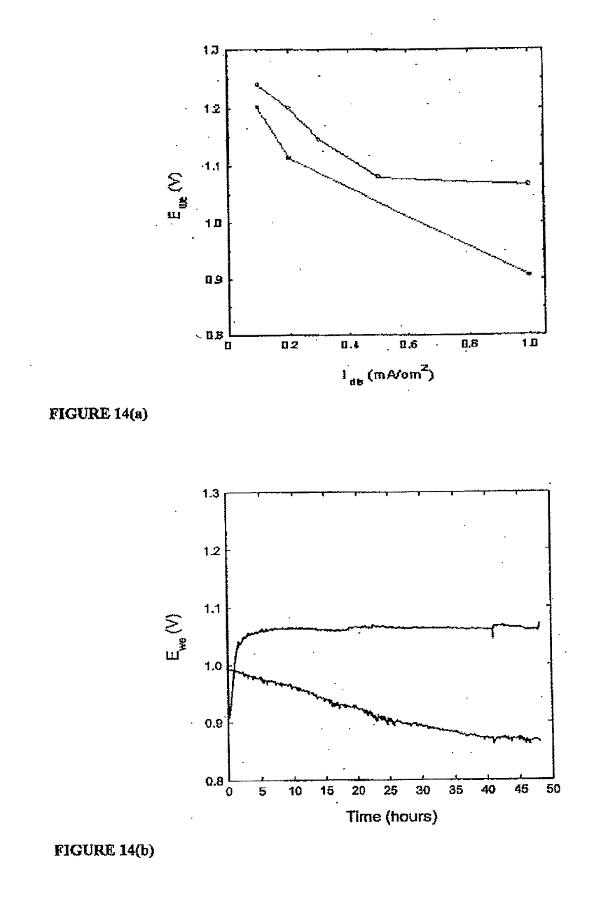

### FIG. 14

FIG. 14 relates to a Zn air battery comprising (i) a PEDOT-Au-Goretex electrode (upper line) and (II) a Pt/Au-Goretex electrode (lower line) wherein FIG. 14(a) is 6 plot of discharge potential Ewe (V) against discharge current (I_{dis}(mA/cm²)) and FIG. 14(b) is a plot of the discharge current (I_{dis}(mA/cm²)) against time (over 48 hours).

The word ‘comprising’ and forms of the word ‘comprising’ as used in this description does not limit the invention claimed fit) exclude any variants or additions.

Modifications and improvements to the invention will be readily apparent to those skilled in the art. Such modifications and improvements are intended to be within the scope of this Invention.

1. An electrode for oxygen reduction comprising a porous organic material and at least one inherently conducting polymer.

2. An electrode according to claim 1 which further comprises a current conductor intermediate the porous organic material and the at least one inherently conducting polymer.

3. An electrode according to claim 1 wherein the inherently conducting polymer is chosen from the group comprising charge transfer complexes and conductive polymers.

4. An electrode according to claim 3 wherein the inherently conducting polymer is chosen from the group comprising polyacetylenes, polypyrroles, polythiophenes, polyanilines, polyfluorenes, poly(3-hexylthiophene), polynaphthalenes, poly(3,4-ethylenedioxythiophene), poly(p-phenylene sulphide), poly(para-phenylenevinylenes) and their derivatives.

5. An electrode according to claim 4 wherein the inherently conducting polymer is chosen from the group comprising PEDOT, ProDOT and substituted PEDOT.

6. An electrode according to claim 3 wherein the inherently conducing polymer additionally includes a non-conducting polymer.

7. An electrode according to claim 1 wherein the porous organic material is chosen from the group comprising polypropylene, polyvinylidene fluoride, polyethylene or cellulosic polymers or combinations thereof.

8. An electrode according to claim 7 wherein the porous organic material is a membrane based on a polymer chosen from the group comprising polytetrafluoroethylene, polyethylene, polyvinylidene fluoride or sulphonated tetrafluoroethylene.

9. An electrode according to claim 2 wherein the current conductor comprises one or more elements in atomic form.

10. An electrode according to claim 9 wherein the current conductor is chosen from the group comprising Au, Ti, Cu, Ag₁ Ni, C, their alloys and alloys with other metals.

11. An electrode according to claim 1 when used with an anode to form a battery.

12. An electrode according to claim 11 wherein the anode comprises at least one reactive metal.

13. A electrode according to claim 12 wherein the reactive metal is chosen from the group comprising zinc, iron, magnesium, manganese, aluminium, lithium or alloys of one or more of said metals.

14. An electrode according to claim 1 when used with an ion-conducting membrane and fuel to form a fuel-cell.

15. The use of an electrode according to claim 14 wherein the fuel is chosen from the group comprising hydrogen, alcohol, borohydride.

16. The use of an electrode according to claim 15 wherein the fuel is methanol.

17. The use of an electrode according to claim 14, wherein the ion-conducting membrane conducts H+.

18. The use of an electrode according to claim 14 wherein the ion-conducting membrane conducts OH—.

19. An electrochemical cell comprising an encapsulating means that encloses:
(a) an electrode for oxygen reduction comprising a porous organic material and at least one inherently conducting polymer,
(b) an anode, and
(c) an electrolyte intermediate the electrodes.

20. An electrochemical cell according to claim 19 wherein (a) is an electrode.

21. An electrochemical cell according to claim 19 wherein the electrochemical cell is a fuel-cell comprising fuel, and the electrolyte is a gas.

22. An electrochemical cell according to claim 21 wherein the fuel-cell comprises an ion-conducting membrane.

23. An electrochemical cell according to claim 21 wherein the fuel is chosen from the group comprising hydrogen, alcohol, borohydride.

24. An electrochemical cell according to claim 23 wherein the fuel is methanol.

25. An electrochemical cell according to claim 22, wherein the ion-conducting membrane conducts H+.

26. An electrochemical cell according to claim 22 wherein the ion-conducting membrane conducts OH—.

27. An electrochemical cell according to claim 19 wherein the electrochemical cell is a metal/air battery and the electrolyte is chosen from the group comprising a liquid, a gel or a solution.

28. An electrochemical cell according to claim 27 wherein the anode comprises at least one reactive metal.

29. An electrochemical cell according to claim 19 wherein the anode is chosen from the group comprising metal anodes, metal alloy anodes and non-metal anodes or combinations thereof.

30. An electrochemical cell according to claim 19 wherein the inherently conducting polymer is coated on one surface of the porous organic material.

31. A method of manufacturing the electrochemical cell of claim 30 including the step of coating the inherently conducting polymer onto the porous organic material by a method chosen from the group comprising vapour phase polymerisation and plasma-polymerisation.

32. A method of manufacturing the electrochemical cell of claim 22 including the step of integrating the ion-conducting membrane with the electrode by a method chosen from the group comprising lamination and direct coating of the ion-conducting membrane onto the electrode.
